(19) United States
(12) Patent Application Publication
(10) Pub. No.: US 2015/0235969 A1
(43) Pub. Date: Aug. 20, 2015

(54) BACKSIDE METALLIZATION PATTERNS FOR INTEGRATED CIRCUITS

(71) Applicants: Hanmin Zhang, Tianjin (CN); Qingchun He, Tianjin (CN); Dehong Ye, Tianjin (CN); Fei Zong, Tianjin (CN)

(72) Inventors: Hanmin Zhang, Tianjin (CN); Qingchun He, Tianjin (CN); Dehong Ye, Tianjin (CN); Fei Zong, Tianjin (CN)

(21) Appl. No.: 14/551,098

(22) Filed: Nov. 24, 2014

(30) Foreign Application Priority Data
Feb. 14, 2014 (CN) 201410128780.8

(51) Int. Cl. H01L 23/00; H01L 21/78

(52) U.S. Cl. CPC H01L 23/562; H01L 21/78; H01L 24/20

(57) ABSTRACT

A semiconductor wafer having multiple dies has a partially metallized backside. After wafer dicing, each of the multiple dies has, on its backside, a metallized area surrounded by a peripheral non-metallization ring. The non-metallization ring allows for easier optical inspection of the dies for determining the extent of any backside chipping caused by the wafer dicing. The peripheral non-metallization rings are generated by not metalizing the areas flanking the saw streets of the wafer.

### BACKGROUND OF THE INVENTION

The present invention relates to integrated circuit device assembly and, more particularly, to wafer dicing or wafer saw singulation.

Typical integrated circuit (IC) fabrication is a multi-step process in which rectangular dies are formed together on a single round semiconductor, e.g., silicon, wafer. Once the deposition and removal steps of component manufacture are completed, the wafer undergoes singulation, where the wafer is diced to separate the individual dies. The singulated dies may then be mounted on corresponding lead frames or substrates and encapsulated with a molding compound to generate individual packaged chips that are ready for mounting on circuit boards. Note that IC device assembly generally includes a second singulation step since, typically, multiple singulated dies are mounted on a metal sheet comprising a corresponding plurality of connected lead frames (or substrates), where the multiple dies and corresponding lead frames are batch-processed during encapsulation to generate a plurality of packaged ICs. The packaged ICs are then singulated or separated from each other, for example using a metal punch that cuts the outer portions of the lead frames to generate individual packaged ICs.

A wafer that is ready for wafer dicing typically has the die's active components on a top side of the wafer and the semiconductor substrate on a bottom side. Wafer dicing may include a preliminary step of wafer thinning, sometimes called backside grinding, where the bottom side is ground down in order to make thinner, lighter, and smaller dies. Wafer dicing may also include a preliminary backside metallization step where the entire bottom side is coated with metal after thinning and before dicing.

Backside metallization may be used to create an electrically conductive contact and/or a better heat-conductive contact for the dies. Backside metallization is common in power devices, such as power quad flat no-lead (PQFN) devices, since metals are highly thermo-conductive and particularly helpful in dissipating heat. As suggested by their name, PQFN devices do not have externally projecting leads. Instead, the devices are mounted on, and connected to, printed circuit boards through metal pads on the bottom and/or sides of the package, typically using solder balls.

Before dicing, an adhesive tape is attached to the wafer backside in order to keep the dies in place during wafer dicing. A wafer saw is typically used to cut up the wafer. A wafer saw is a narrow circular grinding saw, which includes embedded abrasive grit, adapted for cutting wafers, along its cutting edge. The wafer saw cuts along a grid pattern of saw streets, also known as scribe lines, which separate the dies on the wafer. The cutting action of the wafer saw includes both grinding and downward pressure from the top side. By the time the wafer saw cuts through most of the wafer and approaches the bottom side, the thickness of the remaining wafer in the saw street is greatly reduced and this, combined with the downward pressure of the wafer saw, may result in cracking and the breakage of larger pieces of substrate on the bottom side than on the top side. In other words, the severity of backside chipping is often worse than that of topside chipping. The breakage from backside chipping may later cause die cracking and, consequently, device failure if the die is later sufficiently stressed.

Typically, a visual or other optical inspection is performed to determine the extent of backside chipping in any particular die. However, in wafers with backside metallization, it is difficult to visually determine the extent of backside chipping since, although it may be relatively easy to see a crack line from viewing the side of the die, it is often difficult to see the depth of the crack in a bottom view of the die.

### BRIEF DESCRIPTION OF THE DRAWINGS

Other aspects, features, and advantages of the invention will become more fully apparent from the following detailed description, the appended claims, and the accompanying drawings in which like reference numerals identify similar or identical elements. Note that elements in the figures are not drawn to scale.

FIG. 1 shows a bottom view of a wafer having a metallized backside in accordance with one embodiment of the invention;

FIG. 2 shows a detail area of FIG. 1, which includes portions of a cut path and adjoining dies;

FIG. 3 shows a bottom view of a wafer having a metallized backside, in accordance with another embodiment of the invention;

FIG. 4 shows a detail area of FIG. 3;

FIG. 5 shows a bottom view of a wafer having a metallized backside, in accordance with yet another embodiment of the invention;

FIG. 6 shows a detail area of FIG. 5, which includes portions of a cut path, a full die, and a partial die; and

FIG. 7 shows a bottom view of a singulated die of FIG. 1, after wafer dicing.

### DETAILED DESCRIPTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures.

In one embodiment, a wafer backside is metallized such that a peripheral no-metal ring along each die edge surrounds a central metallized area of each die backside. The no-metal ring allows for easier visual inspection of the singulated die for the extent of backside chipping, which will allow for better quality control by flagging dies deemed too-severely chipped. Dies flagged as too-severely chipped may then be discarded or otherwise handled. In addition, the no-metal-ring backside metallization may also reduce the level of backside chipping that occurs during wafer dicing.

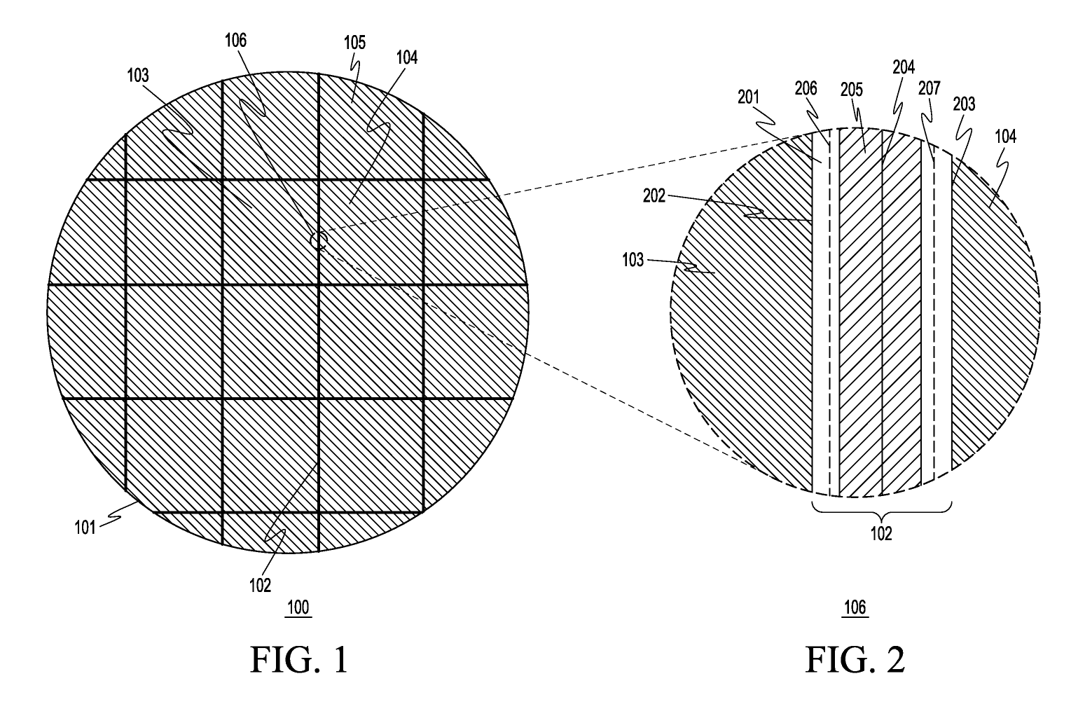

Referring now to FIG. 1, a simplified bottom view of an exemplary wafer 100 having a metallized backside 101 in accordance with one embodiment of the invention is shown. Note that, for simplicity of description, the wafer 100 is shown having an array of eight large full dies and several peripheral partial dies. As would be appreciated by a person of ordinary skill in the art, a typical wafer comprises an array of scores or hundreds of full dies.

The metallization on the backside 101 is indicated by a diagonal-line pattern. The metallized backside 101 comprises a regular rectangular grid of cut paths, including exemplary cut path 102, which goes between, among others, exemplary adjoining dies 103 and 104. The wafer 100 also includes partial dies along its circumference, such as exemplary partial die 105, which are typically discarded after singulation. Partial dies are also separated from adjoining dies, whether partial or whole, by cut paths such as cut path 102. Note that in some alternative implementations, the wafer 100 has only full dies and no partial dies. All of the cut paths include no-metal zones, which are not metallized and comprise, instead, exposed substrate. The no-metal zones form peripheral, rectangular rings around the full die backsides. In other words, the backside 101 of the wafer 100 has an array of non-contiguous metallization zones, which are separated by no-metal zones.

A detail area 106, shown as a dashed circle, which covers a section of the cut path 102 between dies 103 and 104, is described in more detail below. The no-metal zones may be, for example, (1) zones that are metallized along with the rest of backside 101 and from which the metallization is subsequently removed to expose the substrate or (2) zones which do not get metallized, while other portions of backside 101 are metallized to generate metallized backside 101. Backside metallization may be achieved by, for example, vapor deposition or sputtering.

FIG. 2 shows detail area 106 of FIG. 1, which includes portions of cut path 102 and dies 103 and 104. The cut path 102 comprises no-metal zone 201, which extends from metallization edge 202 under die 103 to metallization edge 203 under die 104. In other words, no-metal zone 201, which is exposed wafer substrate material, is co-extensive with the cut path 102. Center line 204 is at the center of the cut path 102 and marks the pre-dicing border between the adjoining dies 103 and 104. Saw street 205, which flanks the center line 204 on both sides and is indicated by a diagonal-line pattern, indicates the section of the wafer 100 that will be removed through grinding in the dicing step by the wafer saw (not shown). The width of the saw street 205 is substantially equal to the width of the wafer saw.

Die edge 206 indicates the edge of the device-component region on the topside of die 103. Die edge 206 is further away from center line 204 than the nearest edge of saw street 205 since device components of the dies should not be removed in the wafer dicing process; only unused border segments should be affected by the dicing. Metallization edge 202 does not extend all the way out to die edge 206. In one implementation, die edge 206 extends about 2 mils+/−1 mils beyond metallization edge 202. Note that a mil is one thousandth of an inch, or about 0.025 millimeters.

Similarly, die edge 207 of die 104 extends about 2 mils beyond metallization edge 203. Note that there may be a narrow buffer area between the edges of saw street 205 and die edges 206 and 207 of dies 103 and 104, respectively, to reduce the risk of inadvertently harming device components of the dies. However, note that die edges 206 and 207 of dies 103 and 104 may extend all the way out to the corresponding edges of saw street 205.

The other cut paths of wafer 100 are substantially similar to cut path 102. This means that each full die of wafer 100 has, on its backside, a no-metal border around a metallized central portion, where the no-metal border—or peripheral ring—extends at least a mil inside from the die edge.

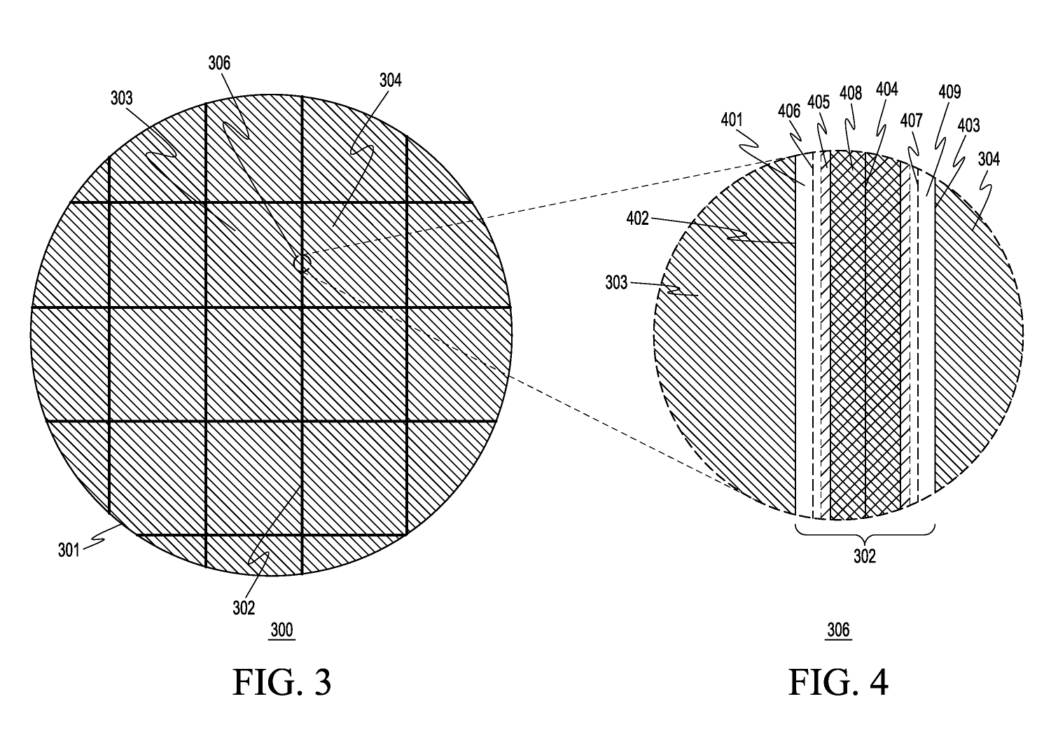

FIG. 3 shows a bottom view of wafer 300 having metallized backside 301, in accordance with another embodiment of the invention. The wafer 300 is substantially similar to the wafer 100 of FIG. 1, with the exception of the layout of the cut paths, including exemplary cut path 302, as described below. Dies 303 and 304 are substantially similar to the corresponding dies of wafer 100. Detail area 306, covering a section of cut path 302 between dies 303 and 304, is described in more detail below.

FIG. 4 shows detail area 306 of FIG. 3. Most of the elements of FIG. 4 are substantially similar to the corresponding elements of FIG. 2 and are similarly labeled, but with a different prefix. Cut path 302 has two narrow no-metal zones 401 and 409 flanking die edges 406 and 407, respectively, rather than the single no-metal zone 201 of FIG. 3. Cut path 302 includes metallization zone 408—indicated by a diagonal-line pattern—flanking center line 404 of cut path 302 and located between no-metal zones 401 and 409. Metallization zone 408 is no wider than saw street 405 and preferably slightly narrower.

No-metal zone 401 extends from a first edge of metallization zone 408 to metallization edge 402 of die 303. Die edge 406 of die 303 is between metallization zone 408 and metallization edge 402. In one implementation, the distance between metallization edge 402 and die edge 406 is 2+/−1 mils.

Similarly, no-metal zone 409 extends from the other edge of metallization zone 408 to metallization edge 403 of die 304. Die edge 407 of die 304 is between metallization zone 408 and metallization edge 403. In one implementation, the distance between metallization edge 403 and die edge 407 is 2+/−1 mils.

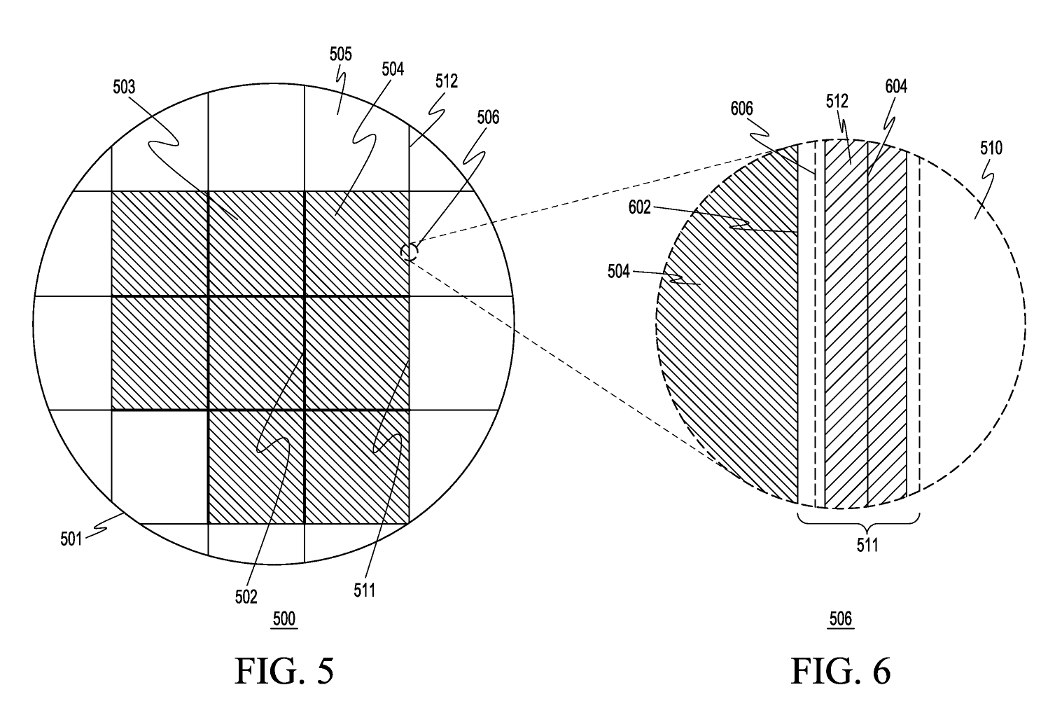

FIG. 5 shows a bottom view of wafer 500 having metallized backside 501, in accordance with yet another embodiment of the invention. Wafer 500 is substantially similar to wafer 100 of FIG. 1, with the exception of the backsides of the partial dies, such as partial dies 505 and 510. The backsides of the partial dies are not metallized. The full dies, such as exemplary dies 503 and 504, are separated by cut paths, such as exemplary cut path 502—which are substantially similar to cut path 102 of FIG. 2. The partial dies, such as dies 505 and 510 are separated from other dies by cut paths such as cut path 511, described in further detail below in reference to FIG. 6, which shows detail area 506 of FIG. 5.

In other words, backside 501 is selectively metallized so that the full dies—such as dies 503 and 504 have metallized sections centered within their respective backsides, where the outer edges of metallized sections are inside of the die edges, preferably at least 1 mil inside. Thus, the die backsides have peripheral no-metal rings surrounding metallization zones. The peripheral rings are preferably at least 1 mil wide. The other sections of backside 501—such as the backsides of the partial dies—are not metallized. This may help reduce the amount of metal used in the fabrication of wafer 500. Note that, although backside metallization is typically performed after device component fabrication, backside metallization—selective or otherwise—may be applied prior to device component fabrication.

FIG. 6 shows detail area 506 of FIG. 5, which includes portions of cut path 511, full die 504, and partial die 510. Cut path 511 comprises saw street 512 flanking center line 604, where center line 604 marks the pre-dicing border between dies 504 and 510. Saw street 512 is indicated by a diagonal-line pattern.

Saw street 512 may extend out to die edge 606 of die 504, though a narrow buffer zone between them is preferable. Die edge 606 indicates the edge of the device-component region on the topside of die 504. The metallized backside area of die 504 extends to metallization edge 602 of die 504. In one implementation, the distance from metallization edge 602 of die 504 to die edge 606 is 2+/−1 mils.

Note that, typically, the width of the peripheral no-metal-zone ring of a die backside is substantially uniform. However, in some implementations different sides of the peripheral rings may have different widths. In addition, in some implementations, the width of any particular side of a peripheral ring may vary and not stay uniform along the entirety of the particular side.

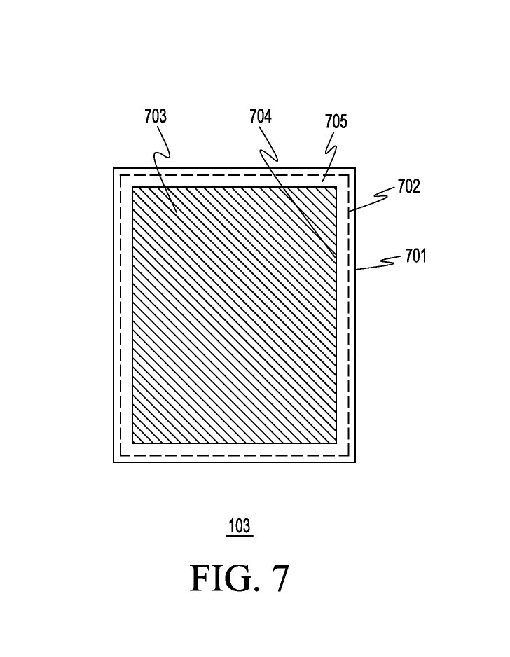

FIG. 7 shows a bottom view of singulated die 103 of FIG. 1, after wafer dicing. Note that other singulated full dies—such as, for example, die 104 of FIG. 1, dies 303 and 304 of FIG. 3, and dies 503 and 504 of FIG. 5—would appear substantially similar. Cut border 701 corresponds to the portions of the saw streets—such as saw street 205 of FIG. 2—that adjoined die 103 prior to singulation. Die border 702 corresponds to the portions of the die edges—such as die edge 206 of FIG. 2—that adjoined die 103 prior to singulation.

Metallization zone 703 is the metallized portion of the backside of die 103. Metallization zone 703 is inside rectangular metallization border 704. Metallization border 704 corresponds to the portions of the metallization edges—such as metallization edge 202 of FIG. 2—that adjoined die 103 prior to singulation. The no-metal zone between metallization border 704 and cut border 701 is peripheral no-metallization ring 705. In other words, the backside of die 103 forms a first rectangle and metallization zone 703 forms a second, smaller, rectangle concentric with the first rectangle—that is to say, the center of the backside of die 103 substantially coincides with the center of metallization zone 703. In one implementation, the width of peripheral no-metallization ring 705 is at least 2 mils.

Embodiments of the invention have been described where the metallized backside area of a die—such as metallization zone 703 of FIG. 7—is a uniformly metallized rectangle within a peripheral no-metallization ring. In alternative embodiments, the metallized area is in a shape other than a rectangle. For example, the metallized area may be in the shape of an oval, a non-rectangular polygon, or a polygon having cut outs. Note that a non-rectangular backside metallization area of a die remains within the corresponding peripheral no-metallization ring of the die.

Embodiments of the invention have been described where the no-metal zones of the metallized backside are exposed wafer substrate. In alternative embodiments, the no-metal zones comprise a non-metallic material covering the wafer substrate.

Implementations of the no-metal-zone edge have been described where the metallization-zone edges are from 1 to 3 mils inward from the corresponding die edge. In alternative implementations, the metallization-zone edges are further in or out from the corresponding die edge.

Embodiments of the invention have been described having particular dimensions defined. In alternative embodiments, the dimensions may vary beyond the described dimension ranges.

It will be further understood that various changes in the details, materials, and arrangements of the parts which have been described and illustrated in order to explain the nature of this invention may be made by those skilled in the art without departing from the scope of the invention as expressed in the following claims.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless explicitly stated otherwise, each numerical value and range should be interpreted as being approximate as if the word “about” or “approximately” preceded the value of the value or range. As used in this application, unless otherwise explicitly indicated, the term “connected” is intended to cover both direct and indirect connections between elements.

The use of figure numbers and/or figure reference labels in the claims is intended to identify one or more possible embodiments of the claimed subject matter in order to facilitate the interpretation of the claims. Such use is not to be construed as limiting the scope of those claims to the embodiments shown in the corresponding figures.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

Although the steps in the following method claims are recited in a particular sequence with corresponding labeling, unless the claim recitations otherwise imply a particular sequence for implementing some or all of those steps, those steps are not necessarily intended to be limited to being implemented in that particular sequence.

1. A semiconductor device, comprising:
a semiconductor die having a topside and an opposing backside, wherein a plurality of device components formed on the die are exposed at the topside, wherein the backside of the die comprises:
a peripheral no-metallization zone located along the periphery of the die; and
a metallization zone, comprising a metal layer, located within the peripheral no-metallization zone.

2. The semiconductor device of claim 1, further comprising:
a lead frame, wherein:
the die is mounted on the lead frame; and
the die and the lead frame are encapsulated with a mold compound.

3. The semiconductor device of claim 2, wherein the semiconductor device is a power quad flat no-lead (PQFN) package.

4. The semiconductor device of claim 1, wherein the peripheral no-metallization zone is 2 mils+/−1 mils wide.

5. The semiconductor device of claim 1, wherein:
the die backside has a first rectangular shape;
the metallization zone has a second rectangular shape smaller than the first rectangular shape;
the die backside and the metallization zone are concentric; and
the peripheral no-metallization zone comprises the area between the die backside and the metallization zone.

6. The semiconductor device of claim 1, wherein:
the die comprises a semiconductor substrate; and
the no-metallization zone comprises exposed semiconductor substrate.

7. A method for assembling a semiconductor device, the method comprising:
forming multiple dies on a semiconductor wafer having a topside and an opposing backside, wherein device components of the dies are exposed on the die topside, and the multiple dies are arranged as an array and separated by a plurality of linear cut paths in a regular grid pattern; and
applying a metallization layer to the wafer backside, wherein each of the cut paths comprises:
a linear saw street indicating a path for a wafer saw for dicing the wafer to generate multiple singulated dies; and
a first no-metallization zone in the backside metallization layer parallel to the saw street.

8. The method of claim 7, wherein the first no-metallization zone is co-extensive with the saw street.

9. The method of claim 7, wherein each of the cut paths further comprises:
a cut-path metallization zone located within the boundaries of the saw street, wherein the first no-metallization zone is located on a first side of the cut-path metallization zone; and
a second no-metallization zone located on a second side of the cut-path metallization zone.

10. The method of claim 7, wherein the saw street lies within and is narrower than the first no-metallization zone such that first and second sides of the first no-metallization zone both extend beyond corresponding first and second sides of the saw street.

11. The method of claim 10, wherein the first and second sides of the first no-metallization zone both extend at least 1 mil beyond the corresponding first and second sides of the saw street.

12. The method of claim 7, wherein:
the array of multiple dies includes a plurality of full dies and a plurality of partial dies; and
the metallization layer comprises an array of non-contiguous metallization zones, wherein each full die and each partial die has a metallization zone.

13. The method of claim 7, wherein:
the array of multiple dies includes a plurality of full dies and a plurality of partial dies;
the metallization layer comprises an array of non-contiguous metallization zones, wherein each full die has a metallization zone; and
the backside of each partial die is not metallized.

14. The method of claim 7, further comprising:
dicing the wafer along the saw streets using the wafer saw to generate multiple singulated dies.

15. The method of claim 14, further comprising:
optically inspecting the multiple singulated dies for backside chipping resulting from the dicing.

16. The method of claim 14, further comprising:
assembling one or more of the singulated dies into one or more IC packages.

17. A semiconductor wafer having a topside and an opposing backside, comprising:
multiple dies having device components exposed on the wafer topside, wherein the multiple dies are arranged in an array;
a plurality of linear cut paths arranged in a grid pattern that separate the multiple dies; and
a metallization layer on the backside, wherein each cut path comprises a first linear no-metallization zone in the backside metallization layer.

18. The wafer of claim 17, wherein:
the wafer comprises a semiconductor substrate; and
the first linear no-metallization zone comprises exposed semiconductor substrate.

19. The wafer of claim 17, wherein each cut path further comprises a second linear no-metallization zone separated from the first linear no-metallization zone by a linear cut-path metallization zone.
